(19) United States
(12) Patent Application Publication
(10) Pub. No.: US 2010/0075177 A1
(43) Pub. Date: Mar. 25, 2010

(54) TNALSPREPARATION METHOD OF ZINC-TIN COMPOSITE TRANSPARENT CONDUCTIVE OXIDE FILMS BY USING ELECTRON CYCLOTRON RESONANCE PLASMA CHEMICAL VAPOR DEPOSITION

(76) Inventors: Joong Kee LEE, Seoul (KR); Byung Won CHO, Seoul (KR); Won Young CHANG, Seoul (KR); Won Young Chang, Seoul (KR); Joo Man WOO, Seoul (KR); Ji Hun Park, Miryang-si (KR)

Correspondence Address: FROMMER LAWRENCE & HAUG LLP, 745 FIFTH AVENUE, NEW YORK, NY, 10151, US

(21) Appl. No.: 12/566,250

(22) Filed: Sep. 24, 2009

(30) Foreign Application Priority Data
Sep. 25, 2008 (KR) 10-2008-0094223
Jul. 8, 2009 (KR) 10-2009-0062238

(51) Int. Cl. B32B 9/00; B01J 19/08; C23C 16/54; H01B 1/02

(52) U.S. Cl. 428/697; 427/576; 118/723 R; 252/519.1

(57) ABSTRACT

The present invention relates to a process of preparing zinc-tin composite transparent conductive oxide films ZnₓSn_{y}O_{z} superior in light transmission, interfacial adhesion strength and electric conductivity by an organic chemical deposition method by using an electron cyclotron resonance (ECR).

Zinc-tin oxide film composite ZnₓSn_{y}O_{z} (x=1, y=8.7, Z=12) stably prepared by an electron-cyclotron chemical vapor deposition according to the present invention is superior to ZnSnO₃ and Zn₂SnO₄ prepared by a physical deposition method in electric conductivity, thereby being applicable in a wide range of electric appliances including a heating element.

### CROSS-REFERENCE TO RELATED APPLICATION

This application claims under 35 U. S.C. §119(a) the benefit of Korean Patent Application Nos. 10-2008-0094223 filed Sep. 25, 2008, and 10-2009-62238 filed Jul. 8, 2009, the entire contents of which are incorporated herein by reference.

### BACKGROUND

(a) Technical Field

The present invention relates to a process of preparing zinc-tin composite transparent conductive oxide films ZnₓSn_{y}O_{z} superior in light transmission, interfacial adhesion strength and electric conductivity by an organic chemical deposition method by using an electron cyclotron resonance (ECR) and a heating element comprising the same.

(b) Background Art

Although examples of a conductive film include ITO (indium tin oxide), tin oxide, zinc oxide (ZnO) and cadmium zinc oxide (CdSnO₄), ITO is widely used because of its high conductivity and visible transparency. Conductive electrons are produced by impurity doping or stoichiometric defects in a semiconductor. ITO modifies this semiconductor and electronically shows a metal-like tendency. In ITO, conductive electrons are produced by the oxygen deficiency in a space in between tin lattice not in a tin-doped surface. Accordingly, the entry of tin into indium indium sites requires a high level of energy. ITO usually contains 5-10 wt % of tin, and tin content is higher than indium content due to a lower price of tin. ITO is superior in electric conductivity and also visible transparent because energy band-gap is higher than 2.5 eV, thus being widely applicable in transparent electrodes of various displays such as LCD, PDP, PDA, a laptop, OA, FA devices, ATM, a touch panel in an automatic ticket-selling machine, a mobile phone, EL backlight electrode in PDA, an electromagnetic shielding or antistatic material and solar cell electrodes. Three major manufacturers of ITO material are Nitto Denko Corporation, Oike & Co., Ltd. and Toyobo Co. in this order (Fuji chimera, 2007).

Essential component in an ITO transparent electrode, indium, is a highly volatile chalcophile element like gallium (Ga) and tantalum (Ta). A small amount of indium can only be found in sulfurized minerals such as sphalerite and stanite, and the average content in the earth's crust is 0.027 ppm. Indium is collected usually during the process of refining sphalerite, zinc, copper, iron, tin sulfides and sulfosalts. However, usage of a rare metal such as indium is abruptly increasing every year because the application is widening in the aforementioned cutting edge industry and related fields such as a semiconductor, LCD, PDP and solar cells, and the price of indium is sharply rising as a result. The price of indium was about 800-1,000 USD/kg in 2006, which is more than twice higher than that of silver (about 400 USD/kg).

Therefore, increasing attention has been drawn to a low-priced a transparent conductive film that can replace ITO without comprising indium, while showing superior conductivity and light transmission. SnO₂-based transparent conductive film is superior in chemical stability and can be used under a high-temperature oxidizing condition. However, the SnO₂-based film is difficult to apply to a wet-etching process. Further, the resistance to high temperature is required of the film for low resistance, which results in wide adoption of a chemical method for manufacture such films appropriate for preparing a high-temperature film. SnO₂:Sb (ATO), Sb-doped SnO₂, is generally known to the resistance of 10⁻³ Ω·cm on a high-temperature substrate although an improved resistance (10⁻⁴ Ω·cm) was reported. SnO₂:F(FTO) can show the resistance of 3-5×10⁻⁴ Ω·cm on a high-temperature glass substrate, and has been put to practical use for special purpose. ZnO-based material is advantageous in that a low-resistance transparent conductive film can be achieved even on a low-temperature substrate and it is low-priced due to the high content of Zn. However, such a film strongly depends on the film-forming techniques or conditions, thus showing a low resistance to acid or base and also to high-temperature oxidizing conditions. The control of oxidizing conditions, while maintaining a relatively high vapor pressure of Zn, is important in preparing a low-resistance thin film. However, no such technique has been developed for the practical application. ZnO:Al (AZO), ZnO:Ga (GZO) and ZnO:B (BZO) films can achieve the resistance of 10⁻⁴ Ω·cm on a high-temperature substrate at low temperature. AZO or GZO film can show the resistance of 2-3×10⁻⁴ Ω·cm at the temperature of 200-350° C. by using magnetron sputtering or arc plasma deposition. Considering the aforementioned advantages in price and resources, ZnO-based film is the most promising as an alternative material to ITO when a large amount of films are used in large-area technique.

Other multi-component oxide transparent conductive films have been developed for controlling the change in the component-dependent properties. For example, MgIn₂O₄, GaIn₂O₃, (Ga,In)₂O₃, Zn₂In₂O₅, Zn₃In₂O₆ and InSn₂O₁₂, although a film-forming temperature is in the range of between room temperature and 350° C. and the surface resistance is 2-8×10⁻⁴ Ω·cm, they comprise indium. Indium-free three-component transparent conductive film (e.g., Zn₂SnO₄ or ZnSnO₃) shows a low surface resistance of 10⁻² or 10⁻³ Ω·cm (Yutaka Sawada (an editorial supervisor), “New development in a transparent conductive film II, published by Shieshi( [symbol] ?), 2002, p. 34).

Meanwhile, the costs of both raw material and a process should be taken into account in manufacturing a transparent conductive film. In₂O₃-based, SnO₂-based and ZnO-based material is high-priced in this order in terms of the cost of raw material. However, this difference in the price of raw material is not practically reflected in the product price when oxide sintered target or organic metal material is purchased as raw material. That is, for example in a magnetron sputtering film-forming technique, the cost necessary for preparing and processing ITO or AZO sintered target is relatively higher. In contrast, the difference in the price of raw material may be reflected in the product price in an arc plasma deposition method because massive oxide sintered pellets may be used.

### SUMMARY OF THE DISCLOSURE

The present inventors have completed the present invention based on the findings that transparent zinc-tin composite oxide films being superior in light transmission, interfacial adhesion strength and conductivity can be prepared by an organic chemical deposition by using an electron cyclotron resonance (ECR).
In an aspect, the present invention provides a process of preparing a transparent conductive oxide film, the process comprising:
(a) forming a high-density plasma ion in a large area by using an electron cyclotron resonance;
(b) forming an over-condensed metal ion by supplying a metal precursor to a lower part where the plasma ion is formed; and
(c) depositing the plasma ion and the over-condensed metal ion onto a polymer substrate surface in a reactor equipped with an ion protection metal shield (IPMS) comprising an ion protection cover and a side plate;
   thereby providing the zinc-tin composite transparent conductive oxide film ZnₓSn_{y}O_{z} having superior light transmission, interfacial adhesion strength and electric conductivity.

In another aspect, the present invention provides a device for preparing zinc-tin composite transparent conductive oxide film ZnₓSn_{y}O_{z}, the device comprising:
(a) an electron cyclotron resonance plasma region comprising a microwave generator(1), a quartz plate(2) and a magnetic current control system(3);
(b) a precursor-supplying system a constant-temperature bath(7) comprising a zinc compound precursor, a constant-temperature bath(8) comprising a tin compound precursor and precursor-carrying gas(9); and
(c) a reaction deposition region comprising a roller(4), an ion protection metal shield(IPMS)(5), a structure in the lower part of a plate(6) and a shower ring(12).

In still another aspect, the present invention provides a transparent conductive zinc-tin composite oxide film and a transparent heating element comprising the film.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 schematically shows an electric field coupled plasma chemical deposition system according to an embodiment of the present invention.

FIG. 2 is an enlarged drawing of an ion protection metal shield.

FIG. 3 shows the distribution of composition in a transparent conductive zinc-tin composite oxide thin film prepared in Example 2 of the present invention.

FIG. 4 is a graph showing the electric conductivity and transmission of a transparent conductive zinc-tin composite oxide prepared in Example 2 of the present invention.

FIG. 5 is a graph showing the light transmission (wavelength region: 500-600 nm) of a transparent conductive zinc-tin composite oxide prepared in Example 2 of the present invention.

FIG. 6 schematically shows a system for the performance test of a transparent heating element comprising a fluorine-doped tin oxide composite of the present invention.

Reference numerals set forth in the Drawings includes reference to the following elements as further discussed below:

1: Microwave generator

2: Quartz plate

3: Magnetic current control system

4: Roller

5: Ion protection metal shield(IPMS)

5A: Ion protection cover

5B: Side plate

6: Structure in the lower part of a plate

7: Zinc compound precursor constant-temperature bath

8: Tin compound precursor constant-temperature bath

9: Precursor-carrying gas

10: Decomposition reaction gas

11: Oxygen gas

12: Shower ring

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to the preferred embodiments of the present invention, examples of which are illustrated in the drawings attached hereinafter, wherein like reference numerals refer to like elements throughout. The embodiments are described below so as to explain the present invention by referring to the figures.

In an aspect, the present invention provides a process of preparing a transparent conductive oxide film, the process comprising:
(a) forming a high-density plasma ion in a large area by using an electron cyclotron resonance;
(b) forming an over-condensed metal ion by supplying a metal precursor to a lower part where the plasma ion is formed; and
(c) depositing the plasma ion and the over-condensed metal ion onto a polymer substrate surface in a reactor equipped with an ion protection metal shield (IPMS) comprising an ion protection cover and a side plate;
providing the zinc-tin composite transparent conductive oxide film ZnₓSn_{y}O_{z} having superior light transmission, interfacial adhesion strength and electric conductivity.

An electron cyclotron resonance plasma system produces high-density plasma ions having a high level of energy by using an electron cyclotron resonance plasma that is generated when the rotation frequency induced by magnetic field of electrons coincides with the microwave frequency of electric source. Metal ions are produced in the supplied metal precursor when low frequency DC positive or negative voltage is applied simultaneously with supplying metal precursors (i.e., organic metal compounds or metal oxides) into an lower part where plasma ions are formed. The metal ions are over-condensed after colliding with organic materials in metal precursors and plasma ions, and deposited onto the surface of polymer substrate through a chemical bonding, thereby forming conductive metal composite thin film. The metal precursor is used in a small amount, and thus has a great deal of influence on the uniformity due to the variation of material delivery depending on the position through which the metal precursor is supplied. Therefore, the metal precursor is preferred to be supplied through the microwave-introducing position right above the electron cyclotron forming region.

An ion protection metal shield (IPMS) is equipped in the reactor in order to prevent impurities from being co-deposited and maintain uniform thickness of films while increasing adhesiveness with the substrate. The ion protection metal shield comprises an ion protection cover and side plates. The ion protection cover causes high-density plasma produced in an electron cyclotron to safely reach the substrate, and also protects plasma ions from being affected by outer electrons existing where the produced plasma remains. In the meantime, among the reacting gases introduced into the substrate, carbonaceous fragments and hydrocarbons can be produced in a reactor due to the gas decomposition or the gas coupling. These hydrocarbons exist in the lower part of a roller because of high-density plasma that reacts onto the substrate from an upper part to a lower part and the direction of a gas sprayed from a showering. The filter of side plates equipped on the sides of the ion protection cover prevents the entrance of hydrocarbons, and causes the separated reactants existing in gas to be discharged with the stream to outside of the reactor. As described above, an IPMS comprises an ion protection cover and side plates the can prevent hydrocarbons, and is composed of two coupled structures. The IPMS concentrates high-density plasma, prevents the entrance of outer hydrocarbon gas and facilitates the introduction of reactant gas onto the substrate, thereby stably preparing zinc-tin oxide composite thin film.

Zinc-tin composite transparent conductive oxide films ZnₓSn_{y}O_{z} can be obtained by the aforementioned preparation method, and the values of x, y and z can be controlled by varying the influx ratio of metal precursors comprising Zn and Sn. The values of x, y and z are in the range of 0.7-1, 8-9 and 11-12, respectively in the transparent conductive zinc-tin composite oxide films ZnₓSn_{y}O_{z}. The zinc-tin composite oxide films herein are superior to the conventional ZnSnO₃-based or Zn₂SnO₄-based material in both electric conductivity and transparency. The electric conductivity is 50-250 [Ω·cm]⁻¹ and light transmission is 90-94%.

Metal composite thin film herein is preferred to be prepared at 25-400° C. Because deposition can be conducted even at room temperature, the preparation method herein is appropriate for forming thin film on a heat-vulnerable substrate. These processes are conducted for from several seconds to several hours.

Moreover, the conventional transparent conductive film experiences thermal deterioration with the lapse of time, and the surface resistance increases up to 3-10 times the resistance. In contrast, it has been ascertained that, when metal composite thin film is doped with fluorine during the chemical deposition or after the preparation process according to the present invention, the metal composite thin film show little thermal denaturalization.

In another aspect, the present invention provides a device for preparing zinc-tin composite transparent conductive oxide film ZnₓSn_{y}O_{z}, the device comprising:
(a) an electron cyclotron resonance plasma region comprising a microwave generator(1), a quartz plate(2) and a magnetic current control system(3);
(b) a precursor-supplying system a constant-temperature bath(7) comprising a zinc compound precursor, a constant-temperature bath(8) comprising a tin compound precursor and precursor-carrying gas(9); and
(c) a reaction deposition region comprising a roller(4), an ion protection metal shield(IPMS)(5), a structure in the lower part of a plate(6) and a shower ring(12).

The electron cyclotron resonance plasma region comprises a microwave generator(1), a quartz plate(2) that separates between microwave-generating region and a reactor region, and a magnetic current control system(3) comprising an electromagnet and a cooling line for controlling heat produced in the electromagnet. The precursor-supplying system comprises a respective constant-temperature bath(7, 8), which comprises zinc and tin for constructing metal oxide composite thin film in the form of a precursor, and a precursor-carrying gas(9) for controlling the influx of the precursor by adjusting temperature-dependent vapor pressure and carrier gas influx. The reaction deposition region comprises a roller(4), which a coating substrate is wound around, for preventing film damage for concentrating high-density plasma, preventing the entrance of outer hydrocarbon gas and facilitating the introduction of reactant gas onto substrate, a structure in the lower part of a plate (6) for preventing the diffusion of reactant gas and a shower ring(12) for uniformly supplying gas and precursor onto the substrate in a reactor.

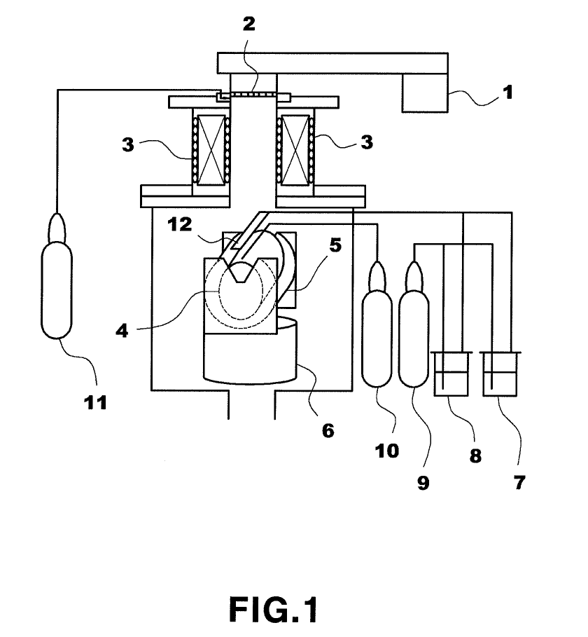

Detailed description of a device for preparing zinc-tin composite oxide films ZnₓSn_{y}O_{z} as shown in FIG. 1. The electron cyclotron resonance plasma region comprises a microwave generator(1) showing a power of up to 2 kW at the frequency of 2.45 GHz, a quartz plate(2) for inducing plasma and separating reactant gases and a magnetic current control system(3) for generating magnetic field of 875 Gauss for the rotation resonance of electrons while increasing current up to 180 A(Ampere). DC positive/negative voltage of between −2 kV and 2 kV can be loaded on grid-shaped electrodes at a low frequency in order to cause over-condensed ions, which are produced by the gas-phase collision of metal precursors with electrons and ions generated by the electron cyclotron resonance in the plasma region, around the substrate and induce the saturation state. Further, the device for preparing zinc-tin oxide composite films ZnₓSn_{y}O_{z} comprises a roller(4) for rotating the substrate, an ion protection metal shield(5) that serves as a separating plate for preventing the diffusion of reactant gas, an lower substrate(6) for supporting the roller, each constant-temperature bath(7,8) for supplying tin and zinc precursors into a bubbler that control vapor pressure by decreasing temperature down to −20° C. in order to adjusting the influx, and a shower ring(12) with a diameter of 0.8 mm for uniformly spraying precursor-carrying gas(9), reactant gas for decomposition (10), oxygen gas(11) and each precursor. Inert gas such as He, Ne and Ar is preferred as the precursor-carrying gas(9) in order to minimize the change in the properties of precursors, and argon (Ar) gas is more preferred. Further, a gas that decomposes by an electron cyclotron resonance plasma and produces electrons is preferred as the reactant gas. For the decomposition, hydrogen gas is usually preferred.

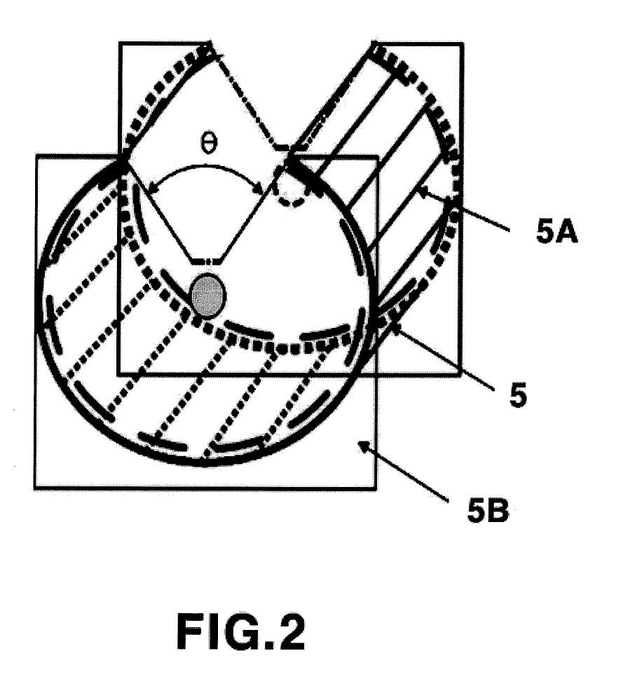

FIG. 2 shows an ion protection metal shield(5) in detail. Thin film deposition occurs between the interface and substrate in an ion protection cover(5A) for preventing the diffusion of reactant gas and a side plate(5B). A roller is equipped inside to achieve a uniform thin film. Preferably, angle (θ) between a substrate and an electron cyclotron plasma is in the range of 50-70°, thus giving fan-shaped space. When the angle is less than 50°, deposition rate can be decreased. When the angle is higher than 70°, specimens can be contaminated.

The pressure of a reactor, where deposition occurs onto the surface of polymeric substrate, is maintained at about 10⁻⁶ Torr by using a system connected with a turbomolecular pump, a roots blower pump and a rotary pump in this order.

The present invention provides to a transparent conductive zinc-tin oxide composite films, ZnₓSn_{y}O_{z} (x, y and z are in the range of 0.7-1, 8-9 and 11-12, respectively). The zinc-tin composite oxide film of the present invention shows electric conductivity of 50-250 [Ω·cm]⁻¹ and optical transparency of 90-94%, thus being superior to the conventional ZnSnO₃-based and Zn₂SnO₄-based oxide film in electric conductivity and transparency.

The present invention also provides a heating element comprising a transparent conductive zinc-tin oxide composite films, ZnₓSn_{y}O_{z} (x, y and z are in the range of 0.7-1, 8-9 and 11-12, respectively).

In a preferred embodiment, the present invention provides a heating element where a transparent conductive zinc-tin oxide composite films, ZnₓSn_{y}O_{z} is deposited on the surface of a polymer.

A zinc-tin composite oxide film of the present invention can be used as a heating element because it is superior in transparency and electric conductivity, and can be easily deposited on the surface of a polymer, and the heating temperature of a zinc-tin composite oxide film herein is 40° C. or higher. In particular, a conventional hot-wire is not preferred for the prevention of frost on a car's windshield because it hampers the vision of a driver. In contrast, a zinc-tin composite oxide film of the present invention can be used as a heating element for preventing frost on a car's windshield because the transparency of zinc-tin oxide composite films of the present invention causes no such problem.

### EXAMPLES

The following examples illustrate the invention and are not intended to limit the same.

### Example 1

### Effect of the Shape of an Ion Protection Metal Shield (IPMS)

The effect of the shape of an ion protection metal shield as shown in FIG. 2 on surface resistance, transmission and uniformity of a fluorine-doped tin oxide transparent conductive film was investigated. The experimental conditions were as follows: microwave power 1500 W, electromagnet current 160 A, process pressure 10 mtorr, roller rotation rate 3 rpm. The amount of introduced gas is follows: tetramethyl tin 4 sccm, oxygen 26.5 sccm, hydrogen 4 sccm, argon(Argon) 15 sccm and SF₆ 0.25 sccm. The distance between a flange at a lower part of an electromagnet and an injection ring was 8 cm, and the distance between the injection ring and a substrate was 4.5 cm. Reaction was conducted for the deposition time of 20 minutes. The following experiments were designed and conducted to optimize the structure of a shied considering mass transfer and flowability of reactants. Surface resistance and transparency of thin films (16 cm×32 cm) were measured by varying the central angle of a fan-shaped space in an ion protection metal shield, which comprises a fan-shaped space on the polymeric surface of which metal ions and plasma ions are deposited with each side of a shield open, and the results are presented in Table 1.

TABLE 1

| | | Average surface | Standard | |
|---|---|---|---|---|
| No. | θ | resistance | deviation | Transparency |
| 1 | 15° | 1.1 | 2241 | 83.8 |
| 2 | 60° | 0.195 | 334.7 | 85.5 |
| 3 | 120° | 2.5 | 2539 | 84.1 |
| 4 | 180° | 3.8 | 7212 | 83.6 |

It was ascertained that surface resistance and photo-transmission are improved when an ion protection metal shield with the angle (θ) of 60° was used. The change in the shape of the ion-protecting metal shield was caused by the change in the size of a small quartz window (diameter: 10 cm) for separating between microwave and a reactor. The ion protection metal shield enabled to uniformly prepare large-area specimens, while minimizing side reactions such as condensation with active species, even at the region where microwave is not irradiated.

### Example 2

### Preparation of ZnₓSn_{y}O_{z} Conductive Films Consisting of Three Components (Zinc, Tin and Oxygen)

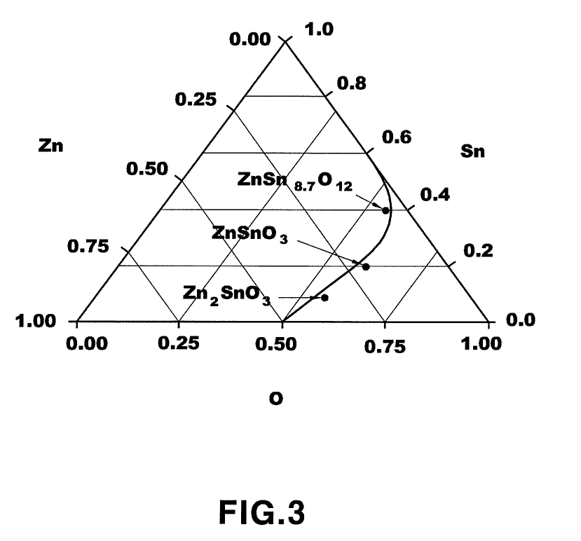

A ZnₓSn_{y}O_{z} conductive film comprising three components of zinc, tin and oxygen with the thickness of 0.1 mm was coated onto poly(ethylene terephthalate) (PET) substrate. The reaction conditions are as follows: temperature 25° C., microwave power 1,000 W, electromagnet current 160 A, deposition pressure in a reactor 10 mTorr, hydrogen 5 sccm, oxygen 26.5 sccm and argon 15 sccm. The distance between a substrate and a nozzle, through which tetramethyl tin (TMT) and diethyl zinc (DEZn) were supplied, was 5 cm, and the distance between a hydrogen nozzle and the substrate was 3 cm. Roller rotation rate was 15 RPM. Bubbler pressure was 70 torr and 50 torr in tetramethyl tin and diethyl zinc, respectively. The ZnₓSn_{y}O_{z} thin film was prepared by varying the influx ratio of TMT/DEZn, while maintaining the constant distance between an electromagnet and an injection ring (3 cm) and the constant distance between an injection ring and the substrate (4 cm). Diagram of the molar ratio in each ZₓSn_{y}O_{z} thin film was presented in FIG. 3, and the properties of the ZnₓSn_{y}O_{z} thin films were shown in Table 2.

TABLE 2

| | Experimental conditions | | | | | | |
|---|---|---|---|---|---|---|---|
| | | | Deposition | IPMS | | | |
| | Hydrogen/Oxygen/Argon/ | Electromagnet | time | (◯, | Resistance | Transmission | Thin film |
| Entry | TMT/DEZn (mol %) | current (A) | (min) | X) | (10⁻⁴ Ωcm) | (%) | thickness |
| 1 | 9.29/53.16/28.77/ | 160 | 5 | X | 280 | 94 | 140 |
| | 7.98/.0.8 | | | | | | |
| 2 | 9.29/53.16/28.77/ | 160 | 5 | ◯ | 39 | 90.3 | 140 |
| | 7.98/.0.8 | | | | | | |
| 3 | 9.21/52.74/28.54/ | 160 | 5 | ◯ | 21 | 91.2 | 140 |
| | 7.91/1.59 | | | | | | |
| 4 | 9.14/52.32/28.31/ | 160 | 5 | ◯ | 37 | 90.8 | 150 |
| | 7.85/2.37 | | | | | | |
| 5 | 9.07/51.91/28.09/ | 160 | 5 | ◯ | 79 | 91.3 | 195 |
| | 7.79/3.13 | | | | | | |
| 6 | 9.00/51.51/27.87/ | 160 | 5 | ◯ | 107 | 93 | 215 |
| | 7.73/3.89 | | | | | | |
| 7 | 8.93/51.11/27.66/ | 160 | 5 | ◯ | 113 | 93 | 205 |
| | 7.67/4.63 | | | | | | |
| 8 | 8.86/50.72/27.45/ | 160 | 5 | ◯ | 145 | 94 | 250 |
| | 7.61/5.36 | | | | | | |
| 9 | 9.29/53.16/28.77/ | 180 | 15 | ◯ | 600 | 87.4 | 600 |
| | 7.98/0.8 | | | | | | |

Table 2 shows the properties of ZnSn_{8.7}O₁₂ (the entries of 3 and 4), ZnSnO₃ (the entries of 5 and 6) and Zn₂SnO₄ (the entries of 7 and 8). The entries of 1 and 2 are drawn to a compound with a higher content of Sn, and the entries of 8 and 9 are drawn to a compound with a higher content of Zn.

As shown in Table 2, surface resistance changes depending on the molar percentage of diethyl zinc while maintaining other process variables. In particular, when diethyl zinc was supplied in the amount of 1.59 mol %, organic carbons in precursors were decomposed by hydrogen plasma, and metal zinc ions with a relatively smaller amount of organic carbons were coated inside tin oxide, thereby forming an oxide film having a relatively lower electric resistance of 21×10⁻⁴ Ω·cm. However, as the molar percentage of diethyl zinc increases, electric resistance of an oxide film increases because a large amount of organic carbons are introduced into the coated films due to the imperfect decomposition of precursors. When the amount of diethyl zinc was higher than 4.0 mol %, a film having an electric resistance of higher than 100×10⁻⁴ Ω·cm was formed. This is because the coated film was formed at a relatively lower concentration of tin ions since zinc ions are saturated inside the film in a gas phase. In contrast, when the molar percentage of diethyl zinc is relatively lower, tin cations stably react with oxygen ions and exist near substrate, thereby forming films at a uniform concentration and resulting in a relatively lower resistance in metal films. However, when the content of diethyl zinc is too high as in the entry 2 above, the concentration of tin ions drastically increases, thus lowering the binding energy of zinc ions and resulting higher resistance than in the entry 3.

Resistance of zinc-doped tin oxide films was also affected by whether IPMS for preventing ions and removing impurities caused by hydrocarbons is used or not. An IPMS protected oxide films from organic carbons in precursors, and also protected oxygen gas and metals separated from precursors (zinc and tin) from carbonyl (—CO) and carboxylic (—COO) groups coupled with organic carbons, thereby increasing zinc doping ratio in tin oxide films and resulting in a lower resistance in oxide films.

When a microwave power is relatively lower, the decomposition of organic hydrocarbons and tin and zinc metals in precursor may be insufficient, a large amount of organic carbons are contained in a coated metal oxide film, and energy level necessary for forming zinc ions decreases. In contrast, a relatively higher microwave power can adversely affect the surface of the deposited metal oxide film, thereby deteriorating photo and electric properties. Accordingly, a microwave power is preferred to be maintained to 1,000 W.

Examples show the resistance results of metal films coated by maintaining the distance between an electromagnet and an injection ring to 3 cm. These experimental results ascertain that, when the distance between an electromagnet and an injection ring is over 3 cm, energy delivered to higher-energy ions and electrons are weakened due to the rotation resonance of electrons in an ECR plasma region. This affected the decomposition of precursors and caused reactant gas to be inert to precursors and polymer substrate, thereby increasing resistance.

When electromagnet current, which can affect the energy of electrons and ions by electron rotation resonance, is higher than 160 A (19.8V), the deformation can be caused by decomposition or coupling of polymer substrate surface due to a relatively higher ion energy. This caused the coated metal oxide film to be molded onto polymer substrate or generated cracks on the surface of coated films, thereby increasing surface resistance.

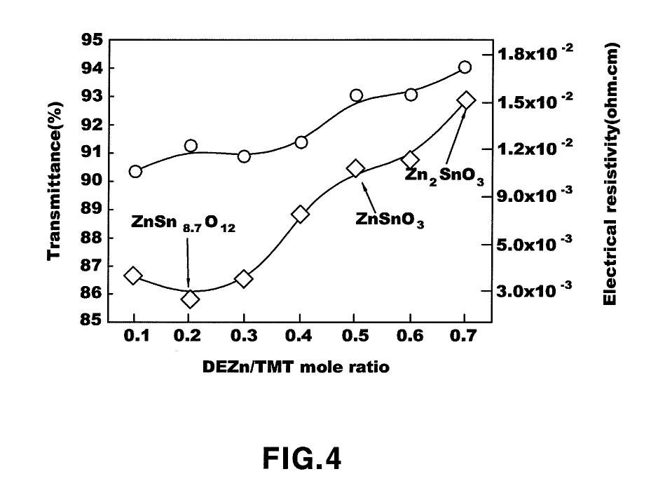

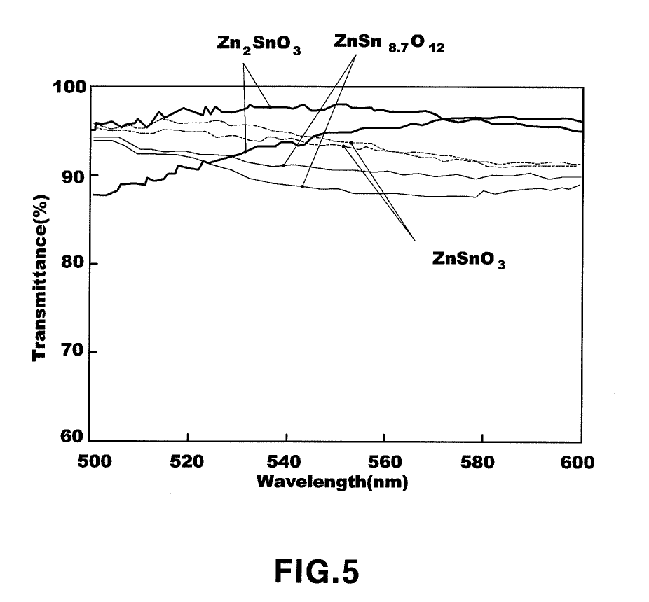

FIG. 4 shows that thus obtained ZnSn_{8.7}O₁₂ thin film is much superior to the conventional ZnSnO₃ and Zn₂SnO₄ in electric conductivity. Although average visible transparency is slightly lowered to 85%, transparency was higher than 90% in the significant region (wavelength of 500-600 nm) as shown in FIG. 5. This ascertains the superiority of ZnSn_{8.7}O₁₂ composite thin film in both electric conductivity and transparency.

As described above, the formation zinc-doped tin oxide film and its electric resistance and light transmission are seriously affected by the change in the feeding ratios of hydrogen/oxygen and tetramethyl tin/diethyl zinc, the shape of an ion metal protecting shield (IPMS) and current in an electromagnet.

### Example 3

### Preparation of ZnₓSn_{y}O_{z} Conductive Film at a Different Temperature

ZnₓSn_{y}O_{z} conductive films comprising three components were coated onto glass substrate under the following conditions: microwave power 1,000 W, electromagnet current 160 A, deposition pressure in a reactor 10 mTorr, hydrogen 5 sccm, oxygen 26.5 sccm and argon 15 sccm. The distance between a substrate and a nozzle, through which tetramethyl tin and diethyl zinc precursors were supplied, was 5 cm, and the distance between a hydrogen nozzle and the substrate was 3 cm. Rotation rate was 15 RPM. Bubbler pressure was 70 torr and 50 torr in tetramethyl tin (TMT) and diethyl zinc (DEZn), respectively, zinc-tin oxide composite films, ZnₓSn_{y}O_{z} thin films were prepared by varying the temperature within 25-600° C., while maintaining the constant distance between an electromagnet and an injection ring (3 cm), the constant distance between an injection ring and a substrate (4 cm) and the constant influx ratio of DEZn/TMT. The properties of the ZnₓSn_{y}O_{z} thin films were presented in Table 3.

TABLE 3

| | Experimental conditions | | | | | | |
|---|---|---|---|---|---|---|---|
| | | | Deposition | | | | |
| | Hydrogen/Oxygen/Argon/ | Electromagnet | time | Temp | Resistance | Transmission | Thin film |
| ENTRY | TMT/DEZn (mol %) | current (A) | (min) | (° C.) | (10⁻⁴ Ωcm) | (%) | thickness |
| 1 | 9.21/52.74/28.54/ | 160 | 5 | 100 | 21 | 91.2 | 140 |
| | 7.91/1.59 | | | | | | |
| 2 | 9.21/52.74/28.54/ | 160 | 5 | 200 | 7 | 91.0 | 140 |
| | 7.91/1.59 | | | | | | |
| 3 | 9.21/52.74/28.54/ | 160 | 5 | 400 | 12 | 91.8 | 140 |
| | 7.91/1.59 | | | | | | |
| 4 | 9.21/52.74/28.54/ | 160 | 5 | 600 | 19 | 89.7 | 140 |
| | 7.91/1.59 | | | | | | |

It was ascertained that electric and photo properties of the deposited thin films were affected by the constant thickness of ZnₓSn_{y}O_{z} thin films and heat transfer to the films on the substrate in an exact and appropriate manner. At a relatively lower temperature of less than 100° C., the gas and DEZn/TMT precursor react and form a uniform deposition film, thereby achieving superior photo properties, while the lower temperature lowers the density of the films, thus resulting in a relatively higher resistance. At the temperature of higher than 400° C., the increased amount of hydrocarbons and impurities separated from the reactant gas in a reactor affect the internal structure of the films, thereby lowering the purity of the films. As a result, photo properties are deteriorated and electric resistance increases.

### Example 4

### Heating Property of Conductive Zinc-Tin Composite Oxide Film

Zinc-tin composite oxide thin films and heating elements with the thickness of 250-300 nm were prepared by using an ion protection metal shield with a central angle θ of 60° in a sector under optimized conditions as follows:

a microwave power of 1,500 W, an electromagnetic current of 160 A, a deposition pressure in a reactor of 10 mTorr, hydrogen flow rate of 9.21 sccm, oxygen flow rate(?) of 52.74 sccm, argon flow rate of 28.54 sccm, tetramethylene tin flow rate of 7.91 sccm, diethyl zinc flow rate of 1.59 sccm, the distance between a substrate and nozzles of diethyl zinc and tetramethyl tin (TMT) of 5 cm, the distance between a substrate and a hydrogen nozzle of 3 cm, a rotation rate of a roller of 7 RPM, bubbler pressure of 50 torr (diethyl zinc) and 70 torr (tetramethyl tin), and the constant distance between a substrate and an electromagnetic injection ring of 3 or 4 cm.

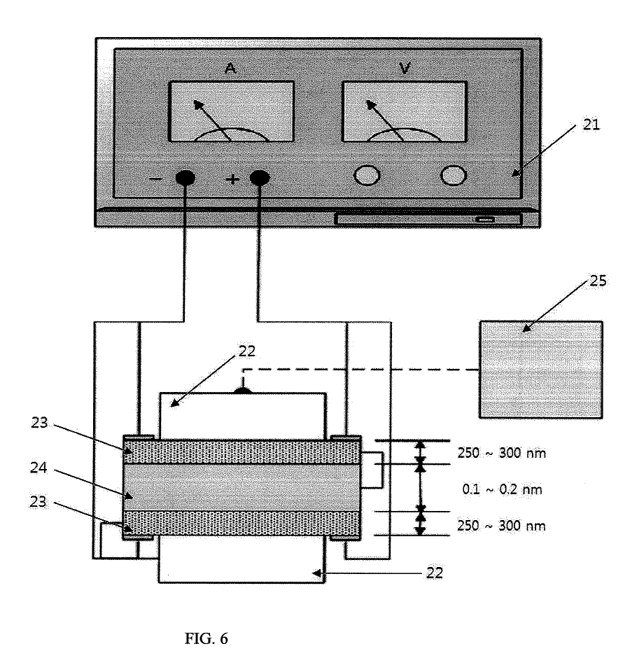

FIG. 6 schematically shows the system for measuring the heating performance test of a transparent heating element. Reference numerals of a system set forth in FIG. 6 includes reference to the following elements:
a variable direct-current voltmeter (21) for measuring various voltages (0-100 V) and generated currents (0-1 A), a glass plate (22) with a uniform thickness of 1.0 mm for measuring temperature, zinc-tin composite oxide thin film (23), PET substrate (24), and contact-type thermometer (25).

Heating thin films were prepared by coating the aforementioned conductive zinc-tin composite oxide thin films (thickness of 250-300 nm) coated on the two surfaces of poly(ethylene terephthalate) (PET) substrate with a thickness of 0.1-0.2 mm. The heating thin films show the surface resistance of 200˜250 Ω/cm² and visible ray transparency of 90%.

A particular voltage was loaded on the surface of the films with a variable direct-current voltmeter, and heat and current resulting from surface resistance were measured. Glass plates were covered and pressed on the two surfaces of the films for the measurement of uniform temperature. Surface temperature was measured by using a contact-type thermometer after the surface temperature became uniform. The heating properties of the fluorine-doped conductive tin oxide composite film are provided in Tables 4 and 5.

TABLE 4
Change in temperature of transparent heating elements
depending on time (loaded voltage 10 V, initial temperature
22° C. and measured current 0.08 A)

| Time (min) | Temperature (° C.) |
|---|---|
| 1 | 26 |
| 2 | 31 |
| 3 | 37 |
| 4 | 38 |
| 5 | 42 |
| 6 | 43 |
| 7 | 44 |
| 8 | 46 |
| 9 | 46 |
| 10 | 46 |
| 30 | 46 |
| 60 | 46 |
| 90 | 46 |
| 120 | 46 |

TABLE 5
Change in temperature, current and film resistance depending
on loaded voltage (elevated voltage: 2.5 voltage/supply count)

| Voltage (V) | Temperature (° C.) | Current (A) | Resistance (R = V/A) |
|---|---|---|---|
| 0.0 | 22 | 0.00 | — |
| 2.5 | 24 | 0.02 | 125 |
| 5.0 | 31 | 0.04 | 125 |
| 7.5 | 37 | 0.06 | 125 |
| 10.0 | 40 | 0.08 | 125 |
| 12.5 | 43 | 0.09 | 139 |
| 15.0 | 50 | 0.10 | 150 |
| 17.5 | 53 | 0.11 | 159 |
| 20.0 | 56 | 0.12 | 167 |
| 24.0 | 63 | 0.14 | 171 |

Table 4 shows the changes in temperature and current on the thin films with time when voltage (10 V) was loaded. At measured current of 0.8 A, temperature gradually increased from the initial temperature of 22° C. and leveled off at the fracture temperature of 46° C.

Table 5 shows the change in temperature, current and film resistance when loaded voltage is increased from 0 V to 20 V in the interval of 2.5 V. Temperature was measured as 40° C. at 10 V, 50° C. at 15 V and 60° C. at 20 V, and temperature was rapidly elevate within a minute. Thin film resistance was calculated by using the measured current and the loaded voltage. However, increase in temperature and current was not ascertained depending on continuous voltage increase because of the characteristics of thin films. Circuit damage due to short circuit on film was followed by abrupt increase in voltage or load of high voltage.

In the present invention, zinc-tin oxide films can be continuously prepared on a polymer substrate surface for a relatively shorter period of time by using a roll to roll system equipped with an ion protection metal shield in combination with an electron magnetic resonance plasma. At the same time, a large-area zinc-doped tin oxide thin film can show a visible light transmission of higher than 90% at 200-900 nm.

In particular, it was ascertained that ZnₓSn_{y}O_{z} (x=1, y=8.7, z=12) prepared by an electron cyclotron chemical vapor deposition is superior to ZnSnO₃ and Zn₂SnO₄ prepared by a physical deposition method in electric conductivity, thereby being applicable in a wide range of electric appliances including a heating element.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A process of preparing a transparent conductive oxide film, the process comprising:
(a) forming a high-density plasma ion in a large area by using an electron cyclotron resonance;
(b) forming an over-condensed metal ion by supplying a metal precursor to a lower part where the plasma ion is formed; and
(c) depositing the plasma ion and the over-condensed metal ion onto a polymer substrate surface in a reactor equipped with an ion protection metal shield (IPMS) comprising an ion protection cover and a side plate;
thereby providing the zinc-tin composite transparent conductive oxide film ZnₓSn_{y}O_{z} having superior light transmission, interfacial adhesion strength and electric conductivity.

2. The process of claim 1, wherein x, y and z in the ZnₓSn_{y}O_{z} are in the range of 0.7-1, 8-9 and 11-12, respectively.

3. The process of claim 1, wherein the metal precursor is an organic metal compound comprising at least one metal selected from the group consisting of tin (Sn) and zinc (Zn) or a metal oxide.

4. The process of claim 1, wherein the deposition is conducted at 25-400° C.

5. The process of claim 1, wherein the electric conductivity and the light transmission are in the range of 50-500 [Ω·cm]⁻¹ and 90-94%, respectively.

6. A device for preparing zinc-tin composite transparent conductive oxide film ZnₓSn_{y}O_{z}, the device comprising:
(a) an electron cyclotron resonance plasma region comprising a microwave generator(1), a quartz plate(2) and a magnetic current control system(3);
(b) a precursor-supplying system a constant-temperature bath(7) comprising a zinc compound precursor, a constant-temperature bath(8) comprising a tin compound precursor and precursor-carrying gas(9); and
(c) a reaction deposition region comprising a roller(4), an ion protection metal shield(IPMS)(5), a structure in the lower part of a plate(6) and a shower ring(12).

7. The device of claim 6, wherein the ion protection metal shield(5) comprises an ion protection cover(5A) and a side plate(5B).

8. A transparent conductive zinc-tin composite oxide film of ZnₓSn_{y}O_{z}, wherein x, y and z are in the range of 0.7-1, 8-9 and 11-12, respectively.

9. A heating element comprising a transparent conductive zinc-tin composite oxide thin film of ZnₓSn_{y}O_{z}, wherein x, y and z are in the range of 0.7-1, 8-9 and 11-12, respectively.

10. The heating element of claim 9, wherein the transparent conductive zinc-tin composite oxide thin film of ZnₓSn_{y}O_{z} is deposited on the surface of a polymer.
